(19) United States
(12) Patent Application Publication
(10) Pub. No.: US 2024/0324409 A1
(43) Pub. Date: Sep. 26, 2024

(54) DISPLAY APPARATUS

(71) Applicant: Samsung Display Co., Ltd., Yongin-Si (KR)

(72) Inventors: Sungwook Lim, Yongin-si (KR); Mingwan Kim, Yongin-si (KR); Yeontae Kim, Yongin-si (KR); Juhyun Shin, Yongin-si (KR); Sungtae Hwang, Yongin-si (KR)

(21) Appl. No.: 18/595,436

(22) Filed: Mar. 5, 2024

(30) Foreign Application Priority Data
Mar. 24, 2023 (KR) 10-2023-0039203
Jul. 5, 2023 (KR) 10-2023-0087396

(51) Int. Cl. H10K 59/80; H10K 102/00

(52) U.S. Cl. CPC H10K 59/873; H10K 59/8793; H10K 2102/311

(57) ABSTRACT

A display apparatus includes a display panel including a first area, a second area, and a bending area disposed between the first area and the second area, a first adhesive layer disposed on the first area, a cover window disposed on the first adhesive layer, and a bending protection layer disposed on the bending area and a portion of the first area disposed adjacent to the bending area, wherein a portion of the bending protection layer is disposed between the display panel and the first adhesive layer, and the portion of the bending protection layer disposed between the display panel and the first adhesive layer includes an inclined surface.

### CROSS-REFERENCE TO RELATED APPLICATION

This application is based on and claims priority under 35 U.S.C. § 119 to Korean Patent Application Nos. 10-2023-0039203, filed on Mar. 24, 2023, and 10-2023-0087396, filed on Jul. 5, 2023, in the Korean Intellectual Property Office, the disclosures of which are incorporated by reference herein in their entireties.

### BACKGROUND

### 1. Field

One or more embodiments relate to a display apparatus, and more particularly, to a display apparatus capable of preventing malfunction and damage of a display panel caused by an electrostatic discharge and also preventing cracks from occurring in the display panel when folded.

### 2. Description of the Related Art

Display apparatuses may be used in a variety of electronic devices. For example, a display apparatus may be used in a mobile electronic apparatus such as a smart phone. A display apparatus may be foldable such that a portion of a display surface may be folded to increase the area of the display surface while reducing an overall size thereof.

A portion of a display panel may be bent to reduce a visible area of a non-display area, and a bending protection layer may be disposed on the bent portion of the display panel. In order to prevent stress from being applied to the display panel due to a slip phenomenon during folding, the bending protection layer and a layer disposed above a non-folding area of the display panel may be located to be spaced apart from each other.

### SUMMARY

An existing display apparatus has a problem in that a display panel malfunctions or is damaged due to static electricity flowing into a portion of the display panel exposed to the outside.

One or more embodiments include a display apparatus capable of preventing malfunction and damage of a display panel caused by an electrostatic discharge and also preventing cracks from occurring in the display panel when folded. Embodiments set forth herein are examples, and embodiments of the disclosure are not limited thereto.

Additional aspects will be set forth in part in the description which follows and, in part, will be apparent from the description, or may be learned by practice of the presented embodiments of the disclosure.

According to one or more embodiments, a display apparatus includes a display panel including a first area, a second area, and a bending area disposed between the first area and the second area, a first adhesive layer disposed on the first area, a cover window disposed on the first adhesive layer, and a bending protection layer disposed on the bending area and a portion of the first area disposed adjacent to the bending area, wherein a portion of the bending protection layer is disposed between the display panel and the first adhesive layer, and the portion of the bending protection layer disposed between the display panel and the first adhesive layer includes an inclined surface.

A portion of the first adhesive layer may be disposed on an inclined surface of the bending protection layer.

A thickness of the portion of the bending protection layer disposed between the display panel and the first adhesive layer may increase toward the bending area.

The display panel may include a first panel surface and a second panel surface opposite to the first panel surface, the bending protection layer may be disposed on the first panel surface, and a first angle between the inclined surface of the bending protection layer and the first panel surface may be from about 2° to about 14°.

The cover window may protrude more than the first adhesive layer toward the bending area.

One side of the cover window disposed adjacent to the bending area may be disposed closer to the bending area than one side of the first adhesive layer disposed adjacent to the bending area in a plan view.

The display apparatus may further include a functional layer disposed between the first adhesive layer and the cover window, and a second adhesive layer disposed between the functional layer and the cover window.

The functional layer may include a polarizing film.

The first area may include a first non-folding area, a second non-folding area, and a foldable area disposed between the first non-folding area and the second non-folding area, wherein the first non-folding area may be disposed spaced apart from the bending area, the second non-folding area may be disposed adjacent to the bending area, and the display panel may be foldable in the foldable area.

The display apparatus may further include an upper protective layer disposed on the cover window, and an upper protective layer adhesive layer disposed between the cover window and the upper protective layer.

According to one or more embodiments, a display apparatus includes a display panel including a first area, a second area, and a bending area disposed between the first area and the second area, a first adhesive layer disposed on the first area, a cover window disposed on the first adhesive layer, a bending protection layer disposed on the bending area and a portion of the first area disposed adjacent to the bending area, and a slip auxiliary layer disposed between the bending protection layer and the first adhesive layer and including a material that is different from a material included in the bending protection layer, wherein a portion of the slip auxiliary layer is disposed between the display panel and the first adhesive layer, and the portion of the slip auxiliary layer disposed between the display panel and the first adhesive layer includes an inclined surface.

A portion of the first adhesive layer may be disposed on an inclined surface of the slip auxiliary layer.

A thickness of the portion of the slip auxiliary layer disposed between the display panel and the first adhesive layer may increase toward the bending area.

The display panel may include a first panel surface and a second panel surface opposite to the first panel surface, the slip auxiliary layer may be disposed on the first panel surface, and a first angle between the inclined surface of the slip auxiliary layer and the first panel surface may be from about 2° to about 14°.

The cover window may protrude more than the first adhesive layer toward the bending area.

One side of the cover window disposed adjacent to the bending area may be disposed closer to the bending area than one side of the first adhesive layer disposed adjacent to the bending area in a plan view.

The display apparatus may further include a functional layer disposed between the first adhesive layer and the cover window, and a second adhesive layer disposed between the functional layer and the cover window.

The functional layer may include a polarizing film.

The first area may include a first non-folding area, a second non-folding area, and a foldable area disposed between the first non-folding area and the second non-folding area, wherein the first non-folding area may be disposed spaced apart from the bending area, the second non-folding area may be disposed adjacent to the bending area, and the display panel may be foldable in the foldable area.

The display apparatus may further include an upper protective layer disposed on the cover window, and an upper protective layer adhesive layer disposed between the cover window and the upper protective layer.

Other aspects, features, and advantages than the above-described aspects, features, and advantages will be apparent from a detailed description, the claims, and the drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view illustrating an unbent state of a display apparatus according to an embodiment;

FIG. 2 is a schematic perspective view illustrating a display apparatus according to an embodiment;

FIG. 3 is a schematic cross-sectional view of the display apparatus taken along line I-I′ of FIG. 2;

FIG. 4 is a schematic plan view illustrating an unbent state of a display panel included in a display apparatus according to an embodiment;

FIG. 5 is an equivalent circuit diagram of a pixel of the display panel of FIG. 4;

FIG. 6 is a schematic cross-sectional view of a portion of a display panel included in a display apparatus according to an embodiment;

FIG. 7 is a schematic cross-sectional view illustrating an enlarged portion A of the display apparatus of FIG. 3;

FIG. 8 is a cross-sectional view illustrating a shape of a first adhesive layer of a display apparatus according to a comparative example;

FIG. 9 is a schematic cross-sectional view illustrating a display apparatus according to an embodiment;

FIG. 10 is a schematic cross-sectional view of a portion of a display apparatus according to another embodiment;

FIG. 11 is a schematic cross-sectional view of an enlarged portion B of the display apparatus of FIG. 10; and

FIG. 12 is a schematic cross-sectional view of a display apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and embodiments thereof will be illustrated in the drawings and will be described herein in detail. The effects and features of the disclosure and the accompanying methods thereof will become apparent from the following description of the embodiments, taken in conjunction with the accompanying drawings. However, the disclosure is not limited to the embodiments described below, and may be embodied in various modes.

In the present specification, it will be understood that although the terms “first,” “second,” etc. may be used herein to describe various elements, these elements should not be limited by these terms. These elements are only used to distinguish one component from another component.

In the present specification, the singular forms “a,” “an,” and “the” are intended to include the plural forms as well, unless the context clearly indicates otherwise.

In the present specification, it will be understood that the terms “includes”, “has, “including”, and/or “having” used herein specify the presence of stated features or elements, but do not preclude the presence or addition of one or more other features or elements.

In the present specification, the expression “A and/or B” indicates A, B, or A and B. Also, the expression “at least one of A and B” indicates A, B, or A and B.

In the present specification, it will be understood that when a layer, region, or component is referred to as being “formed on” another layer, region, or component, it can be directly or indirectly formed on the other layer, region, or component. That is, for example, intervening layers, regions, or components may be present.

In the present specification, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the present specification, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

In the present specification, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

In the present specification, “in a plan view” means when the subject part is viewed from above. That is, in the present specification, “in a plan view” may mean “when viewed from a direction perpendicular to a substrate”.

Hereinafter, example embodiments will be described in detail with reference to the accompanying drawings, and in the description with reference to the drawings, the same or corresponding constituents are indicated by the same reference numerals and redundant descriptions thereof are omitted. Sizes of components in the drawings may be exaggerated for convenience of explanation. For example, since sizes and thicknesses of components in the drawings are arbitrarily illustrated for convenience of explanation, the following embodiments are not limited thereto.

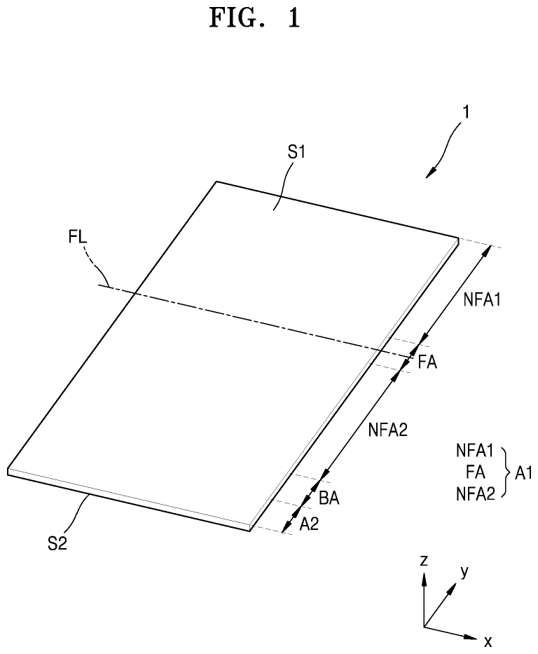

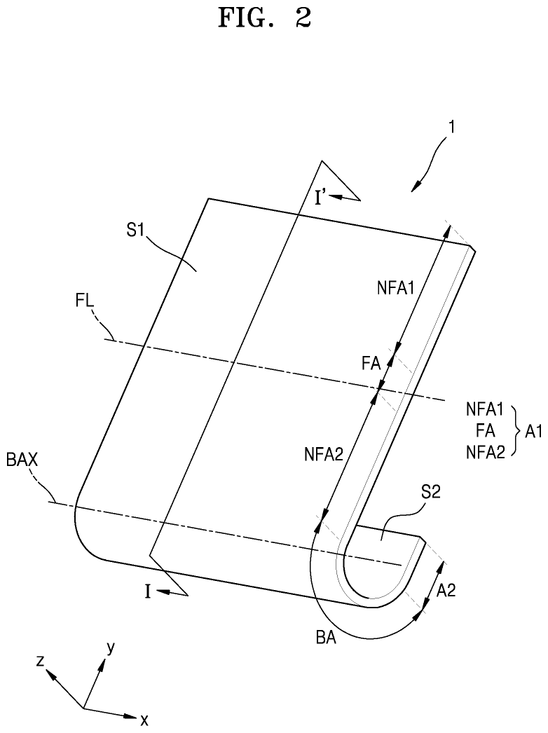

FIG. 1 is a schematic perspective view illustrating an unbent state of a display apparatus 1 according to an embodiment. FIG. 2 is a schematic perspective view illustrating the display apparatus 1 according to an embodiment. That is, FIG. 2 shows a bent state of the display apparatus 1 of FIG. 1.

As shown in FIGS. 1 and 2, the display apparatus 1 may include a first area A1, a second area A2, and a bending area BA positioned between the first area A1 and the second area A2. In detail, the display apparatus 1 may include a first area A1, a bending area BA outside the first area A1, and a second area A2 positioned opposite the first area A1 with respect to the bending area BA.

The first area A1 may include a display area and a non-display area, and the second area A2 may include only a non-display area. Regarding the bending area BA, as shown in FIG. 2, the display apparatus 1 may be bent so that at least a portion of the second area A2 overlaps the first area A1 when viewed in a z-axis direction. In detail, the display apparatus 1 may be bent around a bending axis BAX extending in a first direction (e.g., a +x direction or a −x direction) in the bending area BA. When the display apparatus 1 is bent in the bending area BA, a portion of the non-display area may not be visually recognized when the display apparatus 1 is viewed in a −z direction. Accordingly, the area of the visible non-display area may be reduced.

The display apparatus 1 may include a first surface S1 and a second surface S2 opposite to the first surface S1. The display apparatus 1 may display an image on the first surface S1. That is, the first surface S1 of the display apparatus 1 may include a display surface. Specifically, the first surface S1 of the first area A1 of the display apparatus 1 may include a display surface. When the display apparatus 1 is bent in the bending area BA, the second surface S2 of the first area A1 and the second surface S2 of the second area A2 may face each other.

As shown in FIGS. 1 and 2, the first area A1 may include a first non-folding area NFA1, a second non-folding area NFA2, and a foldable area FA. At least a portion of the display apparatus 1 may be flexible, and as the flexible portion is bent, the display apparatus 1 may be folded. Accordingly, the display apparatus 1 may include a folding area and a non-folding area provided on at least one side of the folding area. In the present specification, “non-folding” means not folding, which includes not only a case of not being flexible and hard to be folded, but also a case of having flexibility but not being folded. The first non-folding area NFA1 and the second non-folding area NFA2 may be non-folding areas, and the foldable area FA may be a flexible and foldable area.

When the display apparatus 1 is not folded, the first non-folding area NFA1 and the second non-folding area NFA2 may be spaced apart from each other in a second direction (e.g., a +y direction or a −y direction) crossing the first direction. The first non-folding area NFA1 may be spaced apart from the bending area BA, and the second non-folding area NFA2 may be disposed adjacent to the bending area BA.

The foldable area FA may be disposed between the first non-folding area NFA1 and the second non-folding area NFA2. Specifically, one side of the foldable area FA may be disposed adjacent to the first non-folding area NFA1, and the other side of the foldable area FA may be disposed adjacent to the second non-folding area NFA2. The foldable area FA may extend in a direction crossing an imaginary straight line connecting the first non-folding area NFA1 to the second non-folding area NFA2. When the display apparatus 1 is not folded, the foldable area FA may extend in the first direction (e.g., the +x direction or the −x direction).

A folding line FL may be provided in the foldable area FA in the first direction (e.g., the +x direction or the −x direction) that is an extending direction of the foldable area FA. Accordingly, the display apparatus 1 may be folded in the foldable area FA. The foldable area FA and the folding line FL of the foldable area FA may overlap an area where an image of the display apparatus 1 is displayed, and when the display apparatus 1 is folded, a portion displaying an image may be folded. That is, the display apparatus 1 may display images not only in the non-folding area but also in the folding area.

For convenience of description, it is illustrated in FIG. 1 that the first non-folding area NFA1 and the second non-folding area NFA2 have the same or similar areas and the display apparatus 1 has one foldable area FA. However, the disclosure is not limited thereto. For example, the first non-folding area NFA1 and the second non-folding area NFA2 may have different areas. Also, the display apparatus 1 may include a plurality of foldable areas FA. In this case, a plurality of non-folding areas may be spaced apart from each other, and each of the plurality of foldable areas FA may be disposed between adjacent non-folding areas. Each foldable area FA may be folded along the folding line FL, and a plurality of folding lines FL may be provided.

It is illustrated in FIG. 1 that the folding line FL passes through the center of the foldable area FA and the foldable area FA is line-symmetric with respect to the folding line FL. However, the disclosure is not limited thereto. For example, the folding line FL may be provided asymmetrically in the foldable area FA.

The display apparatus 1 may be folded so that the first surface S1 of the first non-folding area NFA1 and the first surface S1 of the second non-folding area NFA2 face each other. In other words, as the foldable area FA of the display apparatus 1 is bent, the first surface S1 of the first non-folding area NFA1 and the first surface S1 of the second non-folding area NFA2 may be arranged to face each other. Even when the display apparatus 1 is folded, the foldable area FA may extend in a direction crossing an imaginary straight line connecting the first non-folding area NFA1 to the second non-folding area NFA2. Specifically, when the display apparatus 1 is folded, the foldable area FA may extend in the first direction (e.g., the +x direction or the −x direction) crossing an imaginary straight line (e.g., a straight line parallel to the z-axis direction) connecting the first non-folding area NFA1 to the second non-folding area NFA2.

The foldable area FA may be unfolded again after being bent. Accordingly, the display apparatus 1 may be unfolded. In the present specification, “unfolding” means that the display apparatus 1 which was folded state becomes unfolded state. That is, the display apparatus 1 may be a foldable display apparatus.

In the present specification, the term “folded” means that the shape is not fixed and is transformed from an original shape to another shape, for example, it means that the foldable area FA is folded, curved, or bent along one or more specific lines, that is, the folding line FL. Therefore, when the display apparatus 1 is folded, the first surface S1 of the first non-folding area NFA1 and the first surface S1 of the second non-folding area NFA2 may be arranged parallel to each other and face each other, and the first surface S1 of the first non-folding area NFA1 and the first surface S1 of the second non-folding area NFA2 may form a certain angle (e.g., an acute angle, a right angle, or an obtuse angle) with the foldable area FA disposed therebetween.

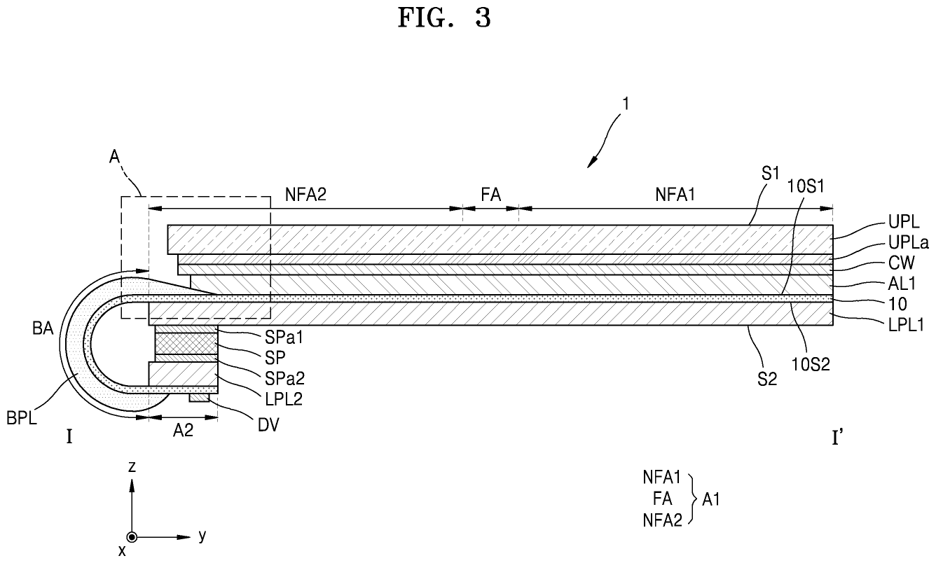

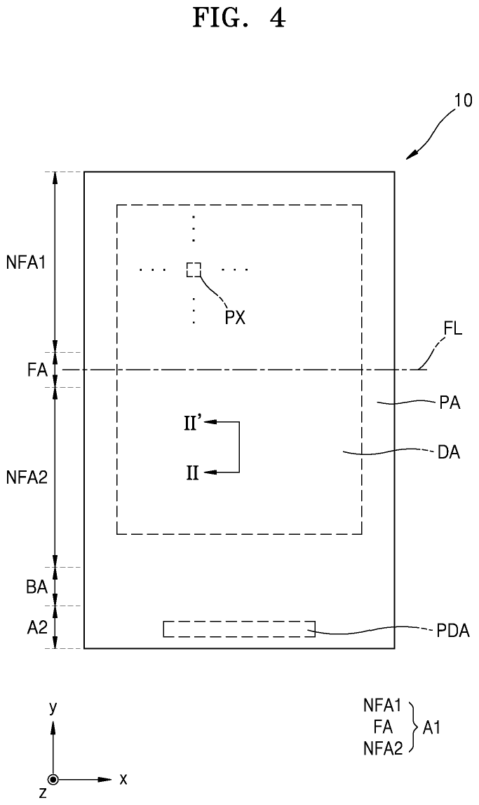

FIG. 3 is a schematic cross-sectional view of the display apparatus 1 taken along line I-I′ of FIG. 2. FIG. 4 is a schematic plan view illustrating an unbent state of a display panel 10 included in the display apparatus 1 according to an embodiment.

As shown in FIG. 3, the display apparatus 1 may include a display panel 10, a cover window CW, an upper protective layer UPL, a first lower protective layer LPL1, a second lower protective layer LPL2, a spacer SP, a driver DV, a bending protection layer BPL, and a first adhesive layer AL1. The display apparatus 1 may further include an upper protective layer adhesive layer UPLa, a first spacer adhesive layer SPa1, and a second spacer adhesive layer SPa2.

The display panel 10 may display images. To this end, the display panel 10 may include a plurality of display elements, and the plurality of display elements may emit light. Accordingly, the display panel 10 may display an image through light emitted from the plurality of display elements. In an embodiment, the display element may be an organic light-emitting diode including an organic emission layer. Alternatively, the display element may be a light-emitting diode (LED). The LED may have a size of a micro scale or a nano scale. For example, the LED may be a micro LED. Alternatively, the LED may be a nanorod LED. The nanorod LED may include gallium nitride (GaN). In an embodiment, a color conversion layer may be disposed on the nanorod LED. The color conversion layer may include quantum dots. Alternatively, the display element may be a quantum dot LED including a quantum dot emission layer. Alternatively, the display element may be an inorganic LED including an inorganic semiconductor. Detailed descriptions of components included in the display panel 10 will be described later.

As described above, the display apparatus 1 may include a first area A1, a second area A2, and a bending area BA disposed therebetween, and the first area A1 may include a first non-folding area NFA1, a second non-folding area NFA2, and a foldable area FA. Because the display apparatus 1 includes the display panel 10, it may be said that the display panel 10 has the first area A1, the second area A2, and the bending area BA, as described above. The first area A1 of the display panel 10 includes the first non-folding area NFA1, the second non-folding area NFA2, and the foldable area FA. Hereinafter, for convenience, the display panel 10 will be described as having the first area A1, the second area A2, and the bending area BA.

The display panel 10 may include a first panel surface 10S1 and a second panel surface 10S2. The first panel surface 10S1 may correspond to the first surface S1 of the display apparatus 1, and the second panel surface 10S2 may correspond to the second surface S2 of the display apparatus 1. That is, the first panel surface 10S1 of the display panel 10 may face the same direction (e.g., the +z direction) as the first surface S1 of the display apparatus 1, and the second panel surface 10S2 of the display panel 10 may face the same direction (e.g., the −z direction) as the second surface S2 of the display apparatus 1. In other words, the display panel 10 may include a first panel surface 10S1 and a second panel surface 10S2 opposite to the first panel surface 10S1.

Specifically, the display panel 10 may be bent in the bending area BA so that at least a portion of the second area A2 overlaps the first area A1 when viewed in the z-axis direction. That is, the display panel 10 may be bent based on a bending axis extending in the first direction (e.g., the +x direction or the −x direction) in the bending area BA. The display panel 10 may display an image on the first panel surface 10S1. That is, the first panel surface 10S1 of the display panel 10 may include a display surface. Specifically, the first panel surface 10S1 of the first area A1 of the display panel 10 may include a display surface. By allowing the display panel 10 to be bent in the bending area BA, the second panel surface 10S2 of the first area A1 and the second panel surface 10S2 of the second area A2 may face each other.

When the display panel 10 is in a state before being folded, the first non-folding area NFA1 and the second non-folding area NFA2 may be spaced apart from each other in the second direction (e.g., the +y direction or the −y direction) crossing the first direction. The first non-folding area NFA1 may be spaced apart from the bending area BA, and the second non-folding area NFA2 may be disposed adjacent to the bending area BA. The foldable area FA may be disposed between the first non-folding area NFA1 and the second non-folding area NFA2 and may extend in the first direction (e.g., the +x direction or the −x direction) crossing an imaginary straight line connecting the first non-folding area NFA1 to the second non-folding area NFA2.

A folding line FL may be provided in the foldable area FA in the first direction (e.g., the +x direction or the −x direction) that is an extending direction of the foldable area FA. Accordingly, the display panel 10 may be folded in the foldable area FA. The display panel 10 may be folded so that the first panel surface 10S1 of the first non-folding area NFA1 and the first panel surface 10S1 of the second non-folding area NFA2 face each other based on the folding line FL. In other words, as the foldable area FA of the display panel 10 is bent, the first panel surface 10S1 of the first non-folding area NFA1 and the first panel surface 10S1 of the second non-folding area NFA2 may be arranged to face each other.

As shown in FIG. 4, the display panel 10 may include a display area DA in which a plurality of pixels PX are arranged and a peripheral area PA positioned outside the display area DA.

Each pixel PX of the display panel 10 is an area capable of emitting light of a certain color, and the display panel 10 may provide an image by using light emitted from the pixels PX. For example, each pixel P may emit red, green, or blue light.

The display area DA is an area providing an image, and may have a polygonal shape including a quadrangle, as shown in FIG. 4. For example, the display area DA may have a rectangular shape in which the horizontal length is longer than the vertical length, a rectangular shape in which the horizontal length is shorter than the vertical length, or a square shape. Alternatively, the display area DA may have various shapes, such as an ellipse or a circle.

The peripheral area PA is a non-display area that does not provide an image and may entirely surround the display area DA. In detail, the pixels PX are not arranged in the peripheral area PA, and a driver or the like for providing electrical signals or power to the pixels PX may be arranged in the peripheral area PA. As shown in FIG. 4, the peripheral area PA may include a pad area PDA, and pads (not shown) may be arranged in the pad area PDA.

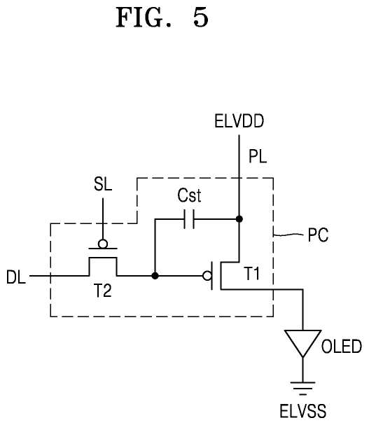

The display area DA may be in the first area A1. A portion of the peripheral area PA may be in the first area A1, another portion of the peripheral area PA may be in the bending area BA, and another portion of the peripheral area PA may be in the second area A2. Specifically, the pad area PDA of the peripheral area PA may be in the second area A2. An electronic chip, a printed circuit board, or the like may be electrically connected to the pads in the pad area PDA. The pads may be arranged spaced apart from one another in the pad area PDA, and the pads may be electrically connected to a plurality of connection lines arranged in the peripheral area PA. The connection lines may electrically connect signal lines arranged in the display area DA, for example, data lines DL (see FIG. 5) (or scan lines SL (see FIG. 5)), to the pads.

The cover window CW may be disposed on the display panel 10. Specifically, the cover window CW may be disposed on the first area A1 of the display panel 10. That is, the cover window CW may be disposed to cover the first panel surface 10S1 of the first area A1 of the display panel 10. The cover window CW may protect the first panel surface 10S1 of the first area A1 of the display panel 10. The cover window CW may be attached on the display panel 10 by the first adhesive layer AL1. The first adhesive layer AL1 may include an adhesive member such as optical clear adhesive (OCA) or pressure sensitive adhesive (PSA). A detailed description of the first adhesive layer AL1 will be described later.

The cover window CW may have high transmittance to transmit light emitted from the display panel 10 and may have a small thickness to reduce the weight of the display apparatus 1. In addition, the cover window CW may have strong strength and hardness to protect the display panel 10 from external impact. The cover window CW may be a flexible window. The cover window CW may protect the display panel 10 while being easily bent according to an external force without cracks. The cover window CW may include glass or plastic. In an embodiment, the cover window CW may include ultra thin glass (UTG) whose strength is enhanced by a method such as chemical strengthening or thermal strengthening. In another embodiment, the cover window CW may include a polymer resin.

The upper protective layer UPL may be disposed on the cover window CW. The upper protective layer UPL may protect the cover window CW and may prevent or reduce scratches on the upper surface of the cover window CW. The upper protective layer UPL may be a plastic film including a polymer resin. For example, the upper protective layer UPL may include at least one of polymer resins, such as polyethyleneterephthalate (PET), poly(butylene terephthalate) (PBT), polycarbonate (PC), polyethylene naphthalate (PEN), polystyrene (PS), polymethylmethacrylate (PMMA), polyvinylchloride (PVC), polyethersulfone (PES), polypropylene (PP), and polyamide (PA).

The upper protective layer adhesive layer UPLa may be disposed between the cover window CW and the upper protective layer UPL. That is, the upper protective layer adhesive layer UPLa may be disposed to cover the cover window CW, and the upper protective layer UPL may be disposed on the upper protective layer adhesive layer UPLa. The upper protective layer adhesive layer UPLa may adhere the cover window CW to the upper protective layer UPL. The upper protective layer adhesive layer UPLa may include an adhesive member such as optically clear adhesive (OCA) or pressure sensitive adhesive (PSA).

Lower protective layers may be disposed on the second panel surface 10S2 of the display panel 10. Specifically, the first lower protective layer LPL1 may be disposed on the second panel surface 10S2 of the first area A1 of the display panel 10, and the second lower protective layer LPL2 may be disposed on the second panel surface 10S2 of the second area A2 of the display panel 10. In other words, because by allowing the display panel 10 to be bent in the bending area BA, the second panel surface 10S2 of the first area A1 and the second panel surface 10S2 of the second area A2 face each other, the first lower protective layer LPL1 may be arranged in the −z direction of the second panel surface 10S2 of the first area A1 of the display panel 10, and the second lower protective layer LPL2 may be arranged in the +z direction of the second panel surface 10S2 of the second area A2 of the display panel 10. The first lower protective layer LPL1 and the second lower protective layer LPL2 may be spaced apart from each other in the bending area BA. That is, because a lower protective layer is not disposed on the second panel surface 10S2 of the bending area BA, the display panel 10 may be easily bent.

The first lower protective layer LPL1 and the second lower protective layer LPL2 may protect the display panel 10 from a physical shock or penetration of foreign materials or moisture into the display panel 10. For example, the first lower protective layer LPL1 and the second lower protective layer LPL2 may absorb physical shock from the outside on the second panel surface 10S2, and each of the first lower protective layer LPL1 and the second lower protective layer LPL2 may block penetration of foreign materials or moisture into the display panel 10. In an embodiment, the first lower protective layer LPL1 and the second lower protective layer LPL2 may each include an organic insulating material such as polyethyleneterephthalate, polyimide (PI), or urethane acrylate.

In some embodiments, the first lower protective layer LPL1 and the second lower protective layer LPL2 may each further include a material that blocks ultraviolet rays (UV). For example, the first lower protective layer LPL1 and the second lower protective layer LPL2 may each include a base resin, an ultraviolet absorber, and inorganic particles. The ultraviolet absorber and inorganic particles may be provided by being dispersed in the base resin. For example, the base resin may be an acrylate-based resin, for example, urethane acrylate. However, the disclosure is not limited thereto, and an optically transparent base resin capable of dispersing an ultraviolet absorber and inorganic particles may be used for the first lower protective layer LPL1 and the second lower protective layer LPL2 without limitation. For example, the ultraviolet absorber may include at least one of benzotriazole-based compound, benzophenone-based compound, salicylic acid-based compound, salicylate-based compound, cyanoacrylate-based compound, cinnamate-based compound, oxanilide-based compound, polystyrene-based compound, azomethine-based compound, and triazine-based compound.

Although not shown in the drawings, an adhesive member may be arranged between the display panel 10 and the first lower protective layer LPL1 and between the display panel 10 and the second lower protective layer LPL2. The first lower protective layer LPL1 and the second lower protective layer LPL2 may be attached to the second panel surface 10S2 of the display panel 10 in the form of a film through the adhesive member. General adhesives known in the art may be employed as the adhesive member without limitation. For example, the adhesive member may be an OCA or a PSA.

As described above, in a state where the bending area BA of the display panel 10 is bent, the second panel surface 10S2 of the first area A1 and the second panel surface 10S2 of the second area A2 may be arranged to face each other. In a state where the bending area BA of the display panel 10 is bent, the spacer SP may be arranged between the second panel surface 10S2 of the first area A1 and the second panel surface 10S2 of the second area A2. The spacer SP may support the display panel 10 in a state where the bending area BA is bent.

The spacer SP may be adhered to each of the lower protective layers through adhesive layers. Specifically, a first spacer adhesive layer SPa1 may be arranged between the first lower protective layer LPL1 and the spacer SP, and a second spacer adhesive layer SPa2 may be arranged between the second lower protective layer LPL2 and the spacer SP. The first spacer adhesive layer SPa1 may adhere the first lower protective layer LPL1 to the spacer SP, and the second spacer adhesive layer SPa2 may adhere the second lower protective layer LPL2 to the spacer SP. The first spacer adhesive layer SPa1 and the second spacer adhesive layer SPa2 may each include an adhesive material such as OCA or PSA.

The driver DV may be disposed on the first panel surface 10S1 of the display panel 10. Specifically, the driver DV may be disposed on the first panel surface 10S1 of the second area A2 of the display panel 10. The driver DV may receive control signals and power supply voltages and generate and output signals and voltages for driving the display panel 10. The driver DV may include an integrated circuit (IC).

The bending protection layer BPL may be disposed on the bending area BA and a portion of the first area A1 disposed adjacent to the bending area BA. Specifically, the bending protection layer BPL may be disposed on the first panel surface 10S1 of the bending area BA and a portion of the first panel surface 10S1 of the first area A1 disposed adjacent to the bending area BA. That is, one end of the bending protection layer BPL and an edge thereof may be positioned on the first area A1 of the display panel 10 disposed adjacent to the bending area BA. Accordingly, the bending protection layer BPL may cover the boundary between the bending area BA and the first area A1. In an embodiment, the bending protection layer BPL may also be disposed on a portion of the second area A2 disposed adjacent to the bending area BA. Specifically, the bending protection layer BPL may also be disposed on a portion of the first panel surface 10S1 of the second area A2 disposed adjacent to the bending area BA. That is, one end of the bending protection layer BPL and an edge thereof may be located on the first area A1 of the display panel 10 disposed adjacent to the bending area BA, and the other end of the bending protection layer BPL and an edge thereof may be located on the second area A2 of the display panel 10 disposed adjacent to the bending area BA. Accordingly, the bending protection layer BPL may cover the boundary between the bending area BA and the first area A1 and the boundary between the bending area BA and the second area A2.

The bending protection layer BPL may protect the bent display panel 10 from external impact and may support the display panel 10 to have a good shape when the display panel 10 is bent. In addition, as the bending protection layer BPL is provided, stress applied to the bending area BA of the display panel 10 may be reduced. When a stacked structure including the display panel 10 is bent, compressive stress or tensile stress may be applied to portions of the stacked structure depending on their positions. A neutral plane, which is a position where compressive stress and tensile stress become zero, may exist in the stacked structure. That is, when the stacked structure including the display panel 10 is bent, compressive stress may be applied to the inside of the stacked structure with respect to the neutral plane, and tensile stress may be applied to the outside of the stacked structure. The further away from the neutral plane, the greater compressive or tensile stress may be applied to a portion of the stacked structure. The bending protection layer BPL may move the neutral plane within the stacked structure including the display panel 10. That is, the stress applied to the bending area BA of the display panel 10 may be adjusted by appropriately adjusting the thickness and/or the modulus of the bending protection layer BPL. Accordingly, stress applied to the display panel 10 may be zero or, at least, minimized.

The bending protection layer BPL may have a high modulus. For example, the bending protection layer BPL may have a modulus of 1,197 MPa at −20° C. and may have a modulus of 232.4 MPa at 25° C. The bending protection layer BPL may include at least one of polyethyleneterephthalate, polybutyleneterephthalate, polymethylmethacrylate, and polyimide. For example, the bending protection layer BPL may include a polymer resin, such as polyethylene terephthalate or polyimide.

FIG. 5 is an equivalent circuit diagram of a pixel PX of the display panel 10 of FIG. 4. As shown in FIG. 5, the pixel PX may include a display element and a pixel circuit PC electrically connected thereto. FIG. 5 shows an organic light-emitting diode OLED as a display element.

The pixel circuit PC may include a first transistor T1, a second transistor T2, and a storage capacitor Cst. The second transistor T2 is a switching transistor and is connected to a scan line SL and a data line DL. The second transistor T2 may be configured to be turned on by a switching signal input from the scan line SL and transfer a data signal input from the data line DL to the first transistor T1. The storage capacitor Cst has one end electrically connected to the second transistor T2 and the other end electrically connected to a driving voltage line PL. The storage capacitor Cst may be configured to store a voltage corresponding to a difference between a voltage received from the second transistor T2 and a driving power supply voltage ELVDD supplied to the driving voltage line PL.

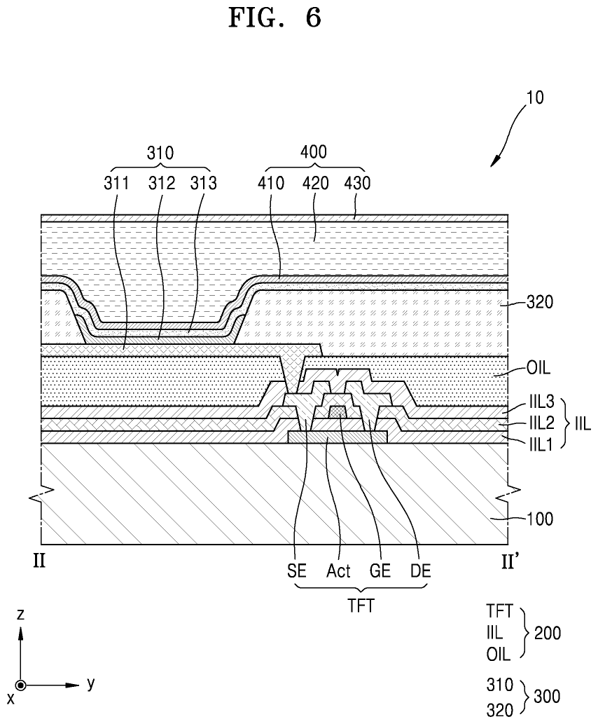

The first transistor T1 is a driving transistor and is connected between the driving voltage line PL and the organic light-emitting diode OLED. The first transistor T1 may be configured to control the amount of driving current flowing from the driving voltage line PL to the organic light-emitting diode OLED in response to a voltage value stored in the storage capacitor Cst. The organic light-emitting diode OLED may emit light having a certain luminance according to the driving current. An opposite electrode 313 (see FIG. 6) of the organic light-emitting diode OLED may receive an electrode power supply voltage ELVSS.

Although FIG. 5 illustrates that the pixel circuit PC includes two transistors and one storage capacitor, the disclosure is not limited thereto. For example, the number of transistors or storage capacitors may be variously changed depending on the design of the pixel circuit PC.

FIG. 6 is a schematic cross-sectional view of a portion of the display panel 10 included in the display apparatus 1 according to an embodiment. Specifically, FIG. 6 is a schematic cross-sectional view illustrating a cross-section taken along line II-II′ of the display panel 10 of FIG. 4.

As shown in FIG. 6, the display panel 10 may include a substrate 100, a pixel circuit layer 200, a display element layer 300, and an encapsulation layer 400. The substrate 100 may include glass, metal or polymer resin. The substrate 100 needs to be flexible or bendable. In this case, the substrate 100 may include a polymer resin such as polyethersulphone, polyacrylate, polyetherimide, polyethylenenaphthalate, polyethyleneterephthalate, polyphenylenesulfide, polyarylate, polyimide, polycarbonate, or cellulose acetate propionate. In addition, the substrate 100 may be variously modified. For example, the substrate 100 may have a multi-layered structure including two layers including the polymer resin and a barrier layer including an inorganic material (e.g., silicon oxide (SiO_{X}), silicon nitride (SiN_{X}), or silicon oxynitride (SiO_{X}N_{Y})) between the two layers.

The pixel circuit layer 200 may be disposed on the substrate 100. The pixel circuit layer 200 may include a thin-film transistor TFT, an inorganic insulating layer IIL, and an organic insulating layer OIL. The thin-film transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, one thin-film transistor TFT is shown in FIG. 6. The thin-film transistor TFT may correspond to the driving thin-film transistor T1 (see FIG. 5) described above.

The semiconductor layer Act may be disposed on the substrate 100. The semiconductor layer Act may include polysilicon. Alternatively, the semiconductor layer Act may include amorphous silicon, an oxide semiconductor, or an organic semiconductor. In an embodiment, the semiconductor layer Act may include a channel region, and a source region and a drain region respectively disposed on both sides of the channel region.

The gate insulating layer IIL1 may be disposed on the semiconductor layer Act and the substrate 100. The gate insulating layer IIL1 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may include zinc oxide (ZnO) and/or zinc peroxide (ZnO₂).

The gate electrode GE may be disposed on the gate insulating layer IIL1. That is, as the gate insulating layer IIL1 is disposed between the semiconductor layer Act and the gate electrode GE, insulation between the semiconductor layer Act and the gate electrode GE may be secured. The gate electrode GE may overlap the channel region of the semiconductor layer Act. The gate electrode GE may include a low-resistance metal material. In an embodiment, the gate electrode GE may include a conductive material including molybdenum (Mo), aluminum (Al), copper (Cu), titanium (Ti), or the like and may have a single-layered or multi-layered structure including the conductive material.

The first interlayer insulating layer IIL2 may be disposed on the gate electrode GE and the gate insulating layer IIL1. The first interlayer insulating layer IIL2 may include an inorganic insulating material such as SiO_{X}, SiN_{X}, SiO_{X}N_{Y}, Al₂O₃, TiO₂, Ta₂O₅, HfO₂, or ZnO_{X}.

The source electrode SE and the drain electrode DE may be disposed on the first interlayer insulating layer IIL2. Each of the source electrode SE and the drain electrode DE may be connected to the semiconductor layer Act through a contact hole formed in the gate insulating layer IIL1 and the first interlayer insulating layer IIL2. At least one of the source electrode SE and the drain electrode DE may include a conductive material including Mo, Al, Cu, Ti, or the like and may have a single-layered or multi-layered structure including the conductive material. In an embodiment, at least one of the source electrode SE and the drain electrode DE may have a multi-layered structure including Ti/Al/Ti layers.

The second interlayer insulating layer IIL3 may be disposed on the source electrode SE, the drain electrode DE, and the first interlayer insulating layer IIL2. The second interlayer insulating layer IIL3 may include an inorganic insulating material such as SiO_{X}, SiN_{X}, SiO_{X}N_{Y}, Al₂O₃, TiO₂, Ta₂O₅, HfO₂, or ZnO_{X}.

The organic insulating layer OIL may be disposed on the second interlayer insulating layer IIL3. The organic insulating layer OIL may substantially planarize an upper portion of the pixel circuit layer 200. The organic insulating layer OIL may include an organic material such as acrylic, benzocyclobutene (BCB), or hexamethyldisiloxane (HMDSO). Although it is illustrated in FIG. 6 that the organic insulating layer OIL includes a single layer, various modifications, such as multiple layers, may be made.

The display element layer 300 may be disposed on the pixel circuit layer 200. The display element layer 300 may include a display element 310 and a pixel-defining layer 320. The display element 310 may be electrically connected to the thin-film transistor TFT. The display element 310 may be, for example, an organic light-emitting diode having a pixel electrode 311, an opposite electrode 313, and an intermediate layer 312 disposed therebetween and including an emission layer. The display element 310 is electrically connected to the thin-film transistor TFT may mean that the pixel electrode 311 of the organic light-emitting diode is electrically connected to the thin-film transistor TFT.

The pixel electrode 311 may contact either the source electrode SE or the drain electrode DE of the driving transistor T1 through a contact hole formed in the second interlayer insulating layer IIL3 and the organic insulating layer OIL to be electrically connected to the driving transistor T1. The pixel electrode 311 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 311 may include a reflective layer including silver (Ag), magnesium (Mg), aluminum (Al), platinum (Pt), palladium (Pd), gold (Au), nickel (Ni), neodymium (Nd), iridium (Ir), chromium (Cr) or a compound thereof. In another embodiment, the pixel electrode 311 may further include a layer including ITO, IZO, ZnO, or In₂O₃ above/below the reflective layer.

The pixel-defining layer 320 may cover an edge of the pixel electrode 311. The pixel-defining layer 320 may have a pixel opening, and the pixel opening may expose the pixel electrode 311. The pixel opening may define an emission area of light emitted from the display element 310. The pixel-defining layer 320 may include an organic insulating material and/or an inorganic insulating material. In some embodiments, the pixel-defining layer 320 may include a light blocking material.

The intermediate layer 312 may be disposed on the pixel electrode 311 and the pixel-defining layer 320. The intermediate layer 312 may include a low molecular weight or high molecular weight material. When the intermediate layer 312 includes a low molecular weight material, the intermediate layer 312 may have a structure in which a hole injection layer (HIL), a hole transport layer (HTL), an emission layer (EML), an electron transport layer (ETL), an electron injection layer (EIL), etc. are stacked in a single or complex structure, and may be formed by a vacuum deposition method. When the intermediate layer 312 includes a high molecular weight material, the intermediate layer 312 may have a structure including an HTL and an EML. In this case, the HTL may include PEDOT, and the EML may include a high molecular weight material such as polyphenylene vinylene (PPV) or polyfluorene The intermediate layer 312 may be formed by screen printing, inkjet printing, laser induced thermal imaging (LITI), or the like. The intermediate layer 312 is not necessarily limited thereto and may have various structures. Furthermore, the intermediate layer 312 may include a layer across a plurality of pixel electrodes 311 or may include a layer patterned to correspond to each of the plurality of pixel electrodes 311.

The opposite electrode 313 may be disposed on the intermediate layer 312 and the pixel-defining layer 320. The opposite electrode 313 may be integrally formed in a plurality of organic light-emitting diodes to correspond to a plurality of pixel electrodes 311. The opposite electrode 313 may include a light-transmitting conductive layer including ITO, In₂O₃, or IZO, and may also include a semi-transmission layer including a metal such as Al or Ag. For example, the opposite electrode 313 may be a semi-transmission layer including Mg or Ag.

The display element 310 may be easily damaged by moisture or oxygen from the outside, and thus, the encapsulation layer 400 may cover the display element 310 to protect the display element 310. As shown in FIG. 6, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include SiO_{X}, SiN_{X}, and/or SiO_{X}N_{Y}. As needed, other layers, such as a capping layer, may be disposed between the first inorganic encapsulation layer 410 and the opposite electrode 313. Because the first inorganic encapsulation layer 410 is formed along a structure thereunder, the upper surface of the first inorganic encapsulation layer 410 may not be flat, as shown in FIG. 6. The organic encapsulation layer 420 may cover the first inorganic encapsulation layer 410, and unlike the first inorganic encapsulation layer 410, the upper surface of the organic encapsulation layer 420 may be substantially flat. The organic encapsulation layer 420 may include one or more materials selected from the group consisting of polyethyleneterephthalate, polyethylenenaphthalate, polycarbonate, polyimide, polyethylenesulfonate, polyoxymethylene, polyarylate, and hexamethyldisiloxane. The second inorganic encapsulation layer 430 may cover the organic encapsulation layer 420 and may include SiO_{X}, SiN_{X}, and/or SiO_{X}N_{Y}.

As described above, the encapsulation layer 400 includes the first inorganic encapsulation layer 410, the organic encapsulation layer 420, and the second inorganic encapsulation layer 430, and thus, even when a crack occurs in the encapsulation layer 400 through the multi-layered structure, the crack may be disconnected between the first inorganic encapsulation layer 410 and the organic encapsulation layer 420 or between the organic encapsulation layer 420 and the second inorganic encapsulation layer 430. Accordingly, the formation of a path through which moisture or oxygen from the outside penetrates into the display panel 10 may be prevented or reduced.

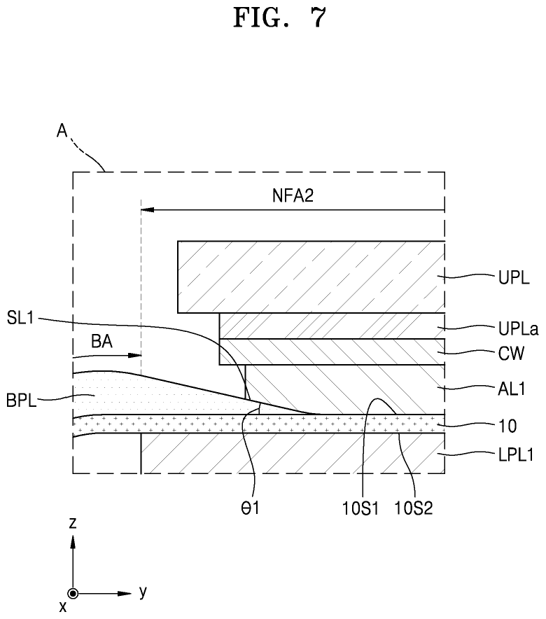

FIG. 7 is a schematic cross-sectional view illustrating an enlarged portion A of the display apparatus 1 of FIG. 3. As described above, the bending protection layer BPL may be disposed not only on the first panel surface 10S1 of the bending area BA, but also on a portion of the first panel surface 10S1 of the first area A1 disposed adjacent to the bending area BA.

As shown in FIG. 7, the first adhesive layer AL1 may be disposed on the first area A1, and a portion of the bending protection layer BPL may be disposed between the display panel 10 and the first adhesive layer AL1. The portion of the bending protection layer BPL disposed between the display panel 10 and the first adhesive layer AL1 may have a first inclined surface SL1. That is, the thickness of the portion of the bending protection layer BPL disposed between the display panel 10 and the first adhesive layer AL1 may increase toward the bending area BA. The first inclined surface SL1 of the bending protection layer BPL and the first panel surface 10S1 of the display panel 10 may form a first angle θ1. A portion of the first adhesive layer AL1 may be disposed on the first inclined surface SL1 of the bending protection layer BPL. That is a portion of the first adhesive layer AL1 may overlap a portion of the bending protection layer BPL in a plan view.

In general, when a display panel is exposed to the outside, static electricity generated during a process of manufacturing the display apparatus or in a finished state may flow into a portion of the display panel exposed to the outside, causing malfunction or damage to the display panel. Specifically, when the first adhesive layer and the bending protection layer are spaced apart from each other, a portion of the display panel disposed between an end of the first adhesive layer and an end of the bending protection layer may be exposed to the outside. Friction may occur between a user and an external object during a manufacturing process or use of the display apparatus, and static electricity may be generated due to the friction. The static electricity may flow into the display panel through a portion of the display panel exposed to the outside. The display panel may malfunction or be damaged due to static electricity introduced into the display panel. That is, the display panel may malfunction or be damaged due to electrostatic discharge (ESD).

However, in the present embodiment, a portion of the first adhesive layer AL1 may overlap a portion of the bending protection layer BPL. That is, the first area A1 of the display panel 10 may be covered by the first adhesive layer AL1 and/or the bending protection layer BPL. Therefore, static electricity may not flow into the display panel 10. Accordingly, the display panel 10 does not malfunction and may not be damaged.

As described above, the display apparatus 1 may be folded in the foldable area FA. In this case, a slip phenomenon, in which adjacent layers stacked with an adhesive layer therebetween, such as the display panel 10, the cover window CW, or the upper protective layer UPL, slides along the surface, may occur. In other words, the display panel 10 may be folded in the foldable area FA. Specifically, when the display panel 10 is folded so that the first panel surface 10S1 of the first non-folding area NFA1 and the first panel surface 10S1 of the second non-folding area NFA2 face each other as the foldable area FA of the display panel 10 is bent, portions of the layers disposed on the first area A1 of the display panel 10 (e.g., the first adhesive layer AL1 or the cover window CW) may move toward the bending area BA. That is, a portion of the first adhesive layer AL1 and a portion of the cover window CW disposed on the second non-folding area NFA2 of the display panel 10 may move toward the bending area BA.

When the bending protection layer BPL does not have the first inclined surface SL1 and thus the side surface of the bending protection layer BPL is in direct contact with the side surface of a layer disposed on the first area A1 of the display panel 10 (e.g., the first adhesive layer AL1 or the cover window CW), the occurrence of a slip phenomenon may not be easy. That is, even though a portion of the first adhesive layer AL1 and a portion of the cover window CW, disposed on the second non-folding area NFA2 of the display panel 10, move toward the bending area BA, the bending protection layer BPL, which is in direct contact with the side surface of the first adhesive layer AL1 and the side surface of the cover window CW, may hinder the movement of the first adhesive layer AL1 and the cover window CW. Stress generated due to this may be applied to the display panel 10 and cracks may occur in the display panel 10.

However, in the present embodiment, because the bending protection layer BPL includes the first inclined surface SL1, the side surface of the bending protection layer BPL may not be in direct contact with the side surface of a layer disposed on the first area A1 of the display panel 10 (e.g., the first adhesive layer AL1 or the cover window CW). Moreover, because the first adhesive layer AL1 is disposed on the first inclined surface SL1, a portion of the first adhesive layer AL1 and a portion of the cover window CW disposed on the second non-folding area NFA2 of the display panel 10 may move toward the bending area BA along the first inclined surface SL1. Therefore, the slip phenomenon may easily occur. Accordingly, cracks may not occur in the display panel 10 because no stress is applied to the display panel 10.

In an embodiment, a first angle θ1 formed between the first inclined surface SL1 of the bending protection layer BPL and the first panel surface 10S1 of the display panel 10 may be from about 2° to about 14°. When the first angle θ1 is less than 2°, the thickness of the bending protection layer BPL may be too small. Accordingly, static electricity may flow into the display panel 10, and the display panel 10 may malfunction or be damaged due to the introduced static electricity. When the first angle θ1 is greater than about 14°, portions of the layers disposed on the first area A1 of the display panel 10 overlapping the bending protection layer BPL may be lifted in the +z direction. That is, a portion of the first area A1 of the display apparatus 1 which is disposed adjacent to the bending area BA may be lifted in the +z direction. Accordingly, display quality of the display apparatus 1 may be degraded due to the lifted layers disposed on the first area A1 of the display panel 10.

In an embodiment, the cover window CW may protrude further toward the bending area BA than the first adhesive layer AL1. In other words, the cover window CW may protrude further in a lateral direction (e.g., a −y direction) than the first adhesive layer AL1. That is, in a plan view, one side of the cover window CW disposed adjacent to the bending area BA may be arranged closer to the bending area BA than one side of the first adhesive layer AL1 disposed adjacent to the bending area BA. In another embodiment, in a plan view, one side of the cover window CW disposed adjacent to the bending area BA may overlap one side of the first adhesive layer AL1 disposed adjacent to the bending area BA.

In general, a cover window having an adhesive layer (e.g., a first adhesive layer) attached to one surface thereof is placed on a display panel and then the cover window is pressed to attach the cover window to the display panel. When the size of the adhesive layer attached to one surface of the cover window is larger than that of the cover window (e.g., when the adhesive layer protrudes more than the cover window in a lateral direction), a portion of the adhesive layer that protrudes more than the cover window in the lateral direction may not be sufficiently pressed when the cover window is pressed.

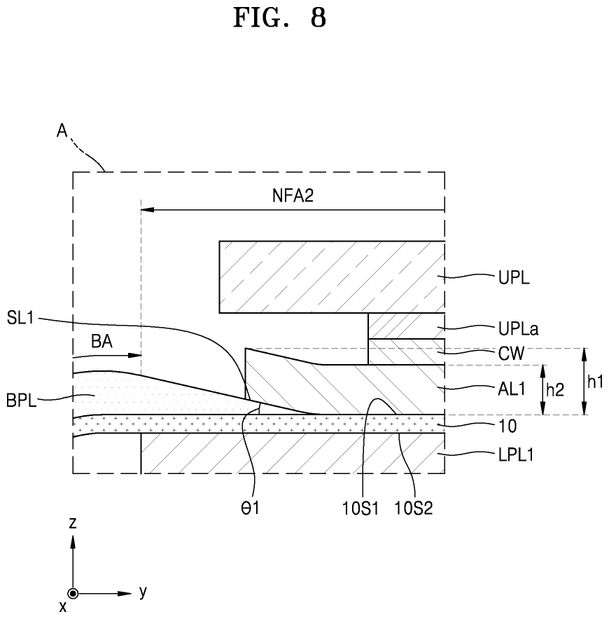

FIG. 8 is a cross-sectional view illustrating a shape of a first adhesive layer of a display apparatus according to a comparative example. As shown in FIG. 8, when the first adhesive layer AL1 protrudes more toward the bending area BA than the cover window CW, a portion of the first adhesive layer AL1 overlapping the bending protection layer BPL may be lifted in the +z direction. In other words one end of the portion of the first adhesive layer AL1 overlapping the bending protection layer BPL has a first height h1, and a portion of the first adhesive layer AL1 that does not overlap the bending protection layer BPL has a second height h2 with respect to the first panel surface 10S1 of the display panel 10. The first height h1 is higher than the second height h2. Accordingly, because the upper surface (in the +z direction) of the first adhesive layer AL1 is not flat, the display quality of the display apparatus 1 may deteriorate.

However, in the case of the display apparatus 1 according to the present embodiment, the cover window CW may protrude more toward the bending area BA than the first adhesive layer AL1. Accordingly, when the cover window CW is pressed during the process of manufacturing the display apparatus 1, the first adhesive layer AL1 may be sufficiently pressed. Therefore, the upper surface (in the +z direction) of the first adhesive layer AL1 may be flat and the display quality of the display apparatus 1 may not deteriorate.

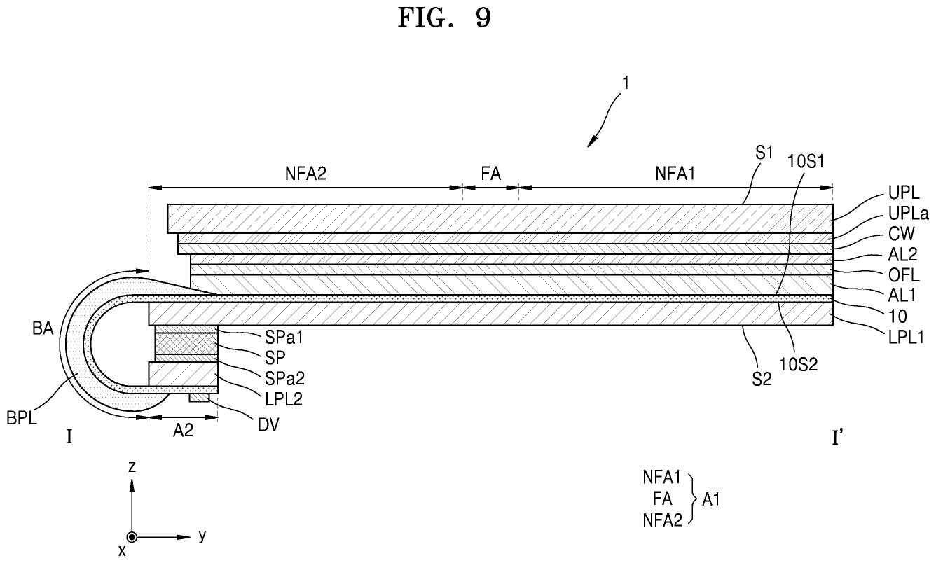

Although FIGS. 3 and 7 show that the first adhesive layer AL1 and the cover window CW are in direct contact with each other, the disclosure is not limited thereto. As shown in FIG. 9, which is a schematic cross-sectional view of the display apparatus 1 according to an embodiment, a functional layer OFL and a second adhesive layer AL2 may be disposed between the first adhesive layer AL1 and the cover window CW.

The functional layer OFL may be disposed between the first adhesive layer AL1 and the cover window CW. Specifically, the functional layer OFL may be disposed on the first adhesive layer AL1. In an embodiment, the functional layer OFL may be an optical functional layer that reduces reflectance of light (e.g., external light) incident toward the display panel 10 from the outside. Accordingly, the functional layer OFL may improve color purity of light emitted from the display panel 10. The functional layer OFL may include a polarizing film including a phase retarder and a polarizer. The phase retarder may include a W2 phase retarder and/or a N4 phase retarder. In this case, the first adhesive layer AL1 may be disposed between the functional layer OFL and the display panel 10. The first adhesive layer AL1 may attach the functional layer OFL to the display panel 10.

The second adhesive layer AL2 may be disposed between the functional layer OFL and the cover window CW. Specifically, the second adhesive layer AL2 may be disposed on the functional layer OFL. The cover window CW may be attached on the functional layer OFL by the second adhesive layer AL2. The second adhesive layer AL2 may include an adhesive member such as OCA or PSA.

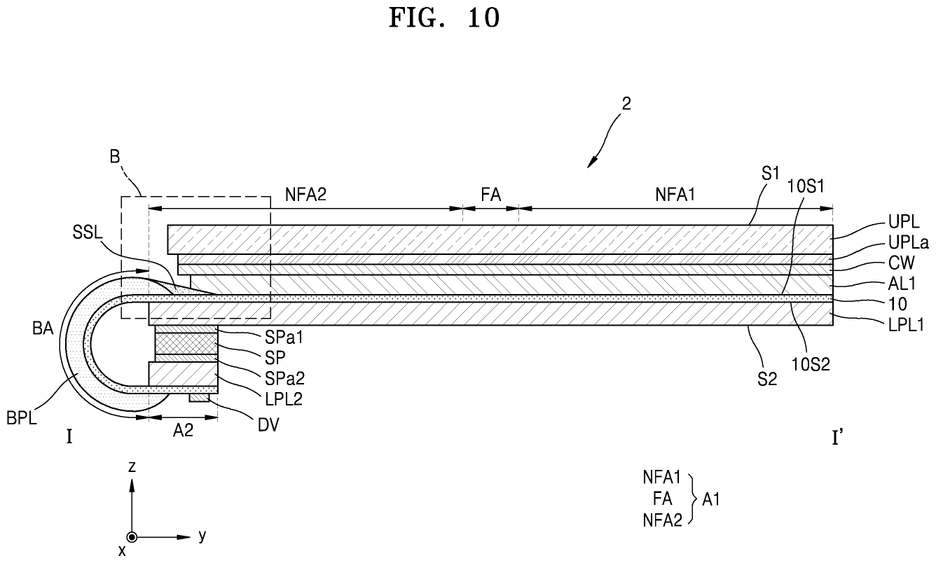

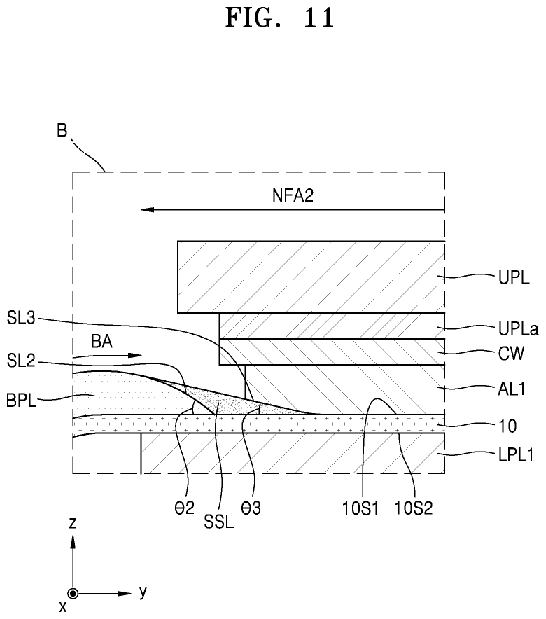

FIG. 10 is a schematic cross-sectional view of a portion of a display apparatus 2 according to another embodiment, and FIG. 11 is a schematic cross-sectional view of an enlarged portion B of the display apparatus 2 of FIG. 10. Because the display apparatus 2 according to the present embodiment is similar to the display apparatus 1 described above with reference to FIGS. 1 to 7, differences from the display apparatus 1 described above with reference to FIGS. 1 to 7 will be mainly described below. In FIGS. 10 and 11, the same reference numerals as those in FIGS. 1 to 7 denote the same members, and thus, duplicate descriptions are omitted.

The display apparatus 1 described above with reference to FIGS. 1 to 7 may include the display panel 10, the cover window CW, the upper protective layer UPL, the first lower protective layer LPL1, the second lower protective layer LPL2, the spacer SP, a driver DV, the bending protection layer BPL, the first adhesive layer AL1, the upper protective layer adhesive layer UPLa, the first spacer adhesive layer SPa1, and the second spacer adhesive layer SPa2. The bending protection layer BPL of the display apparatus 1 described above with reference to FIGS. 1 to 7 may be disposed on the bending area BA and a portion of the first area A1 adjacent to the bending area BA. Specifically, the bending protection layer BPL may be disposed on the first panel surface 10S1 of the bending area BA and a portion of the first panel surface 10S1 of the first area A1 disposed adjacent to the bending area BA. As shown in FIG. 10, even in the case of the display apparatus 2 according to the present embodiment, the display apparatus 2 may include a display panel 10, a cover window CW, an upper protective layer UPL, a first lower protective layer LPL1, a second lower protective layer LPL2, a spacer SP, a driver DV, a bending protection layer BPL, a first adhesive layer AL1, an upper protective layer adhesive layer UPLa, a first spacer adhesive layer SPa1, and a second spacer adhesive layer SPa2. The bending protection layer BPL of the display apparatus 2 may be disposed on a bending area BA and a portion of a first area A1 disposed adjacent to the bending area BA.

However, as shown in FIGS. 10 and 11, a portion of the bending protection layer BPL may not be disposed between the display panel 10 and the first adhesive layer AL1. That is, the first adhesive layer AL1 and the bending protection layer BPL may be spaced apart from each other. That is, a portion of the first adhesive layer AL1 may not overlap a portion of the bending protection layer BPL in a plan view. Therefore, the bending protection layer BPL may not be disposed between the display panel 10 and the first adhesive layer AL1. The bending protection layer BPL of the display apparatus 2 according to the present embodiment may be disposed on the bending area BA and a portion of the first area A1 disposed adjacent to the bending area BA, but a portion of the bending protection layer BPL may not be disposed between the display panel 10 and the first adhesive layer AL1.

In the case of the display apparatus 2 according to the present embodiment, the display apparatus 2 may further include a slip auxiliary layer SSL. The slip auxiliary layer SSL may be arranged between the first adhesive layer AL1 and the bending protection layer BPL. A portion of the slip auxiliary layer SSL may be disposed between the display panel 10 and the first adhesive layer AL1. That is, a portion of the first adhesive layer AL1 may overlap a portion of the slip auxiliary layer SSL in a plan view. In other words, a portion of the slip auxiliary layer SSL may be disposed between the display panel 10 and the first adhesive layer AL1. Another portion of the slip auxiliary layer SSL may overlap a portion of the bending protection layer BPL. That is, another portion of the slip auxiliary layer SSL may be disposed on the bending protection layer BPL. In other words, another portion of the slip auxiliary layer SSL may cover a portion of the bending protection layer BPL disposed on a portion of the first panel surface 10S1 of the first area A1.

As shown in FIG. 11, the bending protection layer BPL disposed on a portion of the first panel surface 10S1 of the first area A1 may has a second inclined surface SL2. That is, the thickness of a portion of the bending protection layer BPL disposed on a portion of the first panel surface 10S1 of the first area A1 may increase toward the bending area BA. The second inclined surface SL2 of the bending protection layer BPL and the first panel surface 10S1 of the display panel 10 may form a second angle θ2.

A portion of the slip auxiliary layer SSL disposed between the display panel 10 and the first adhesive layer AL1 may has a third inclined surface SL3. That is, the thickness of a portion of the slip auxiliary layer SSL disposed between the display panel 10 and the first adhesive layer AL1 may increase toward the bending area BA. The third inclined surface SL3 of the slip auxiliary layer SSL and the first panel surface 10S1 of the display panel 10 may form a third angle θ3. A portion of the first adhesive layer AL1 may be disposed on the third inclined surface SL3 of the slip auxiliary layer SSL. That is, a portion of the first adhesive layer AL1 may overlap a portion of the slip auxiliary layer SSL in a plan view. In other words, a portion of the slip auxiliary layer SSL may be disposed between the display panel 10 and the first adhesive layer AL1.

The descriptions provided above with reference to FIGS. 1 to 7 regarding an effect when a portion of the first adhesive layer AL1 overlaps a portion of the bending protection layer BPL and an effect when the bending protection layer BPL includes the first inclined surface SL1 may also be applied to an effect when a portion of the first adhesive layer AL1 overlaps a portion of the slip auxiliary layer SSL and an effect when the slip auxiliary layer SSL includes the third inclined surface SL3, and thus, redundant descriptions thereof are omitted.

In an embodiment, a third angle θ3 formed between the third inclined surface SL3 of the slip auxiliary layer SSL and the first panel surface 10S1 of the display panel 10 may be about 2° to about 14°. When the third angle θ3 is less than about 2°, the thickness of the slip auxiliary layer SSL may be too thin. Accordingly, static electricity may flow into the display panel 10, and the display panel 10 may malfunction or be damaged due to the introduced static electricity. When the third angle θ3 is greater than about 14°, portions of layers disposed on the first area A1 of the display panel 10 overlapping the slip auxiliary layer SSL may be lifted in the +z direction. That is, a portion of the first area A1 of the display apparatus 2 which is disposed adjacent to the bending area BA may be lifted in the +z direction. Accordingly, the display quality of the display apparatus 2 may deteriorate due to the lifted layers disposed on the first area A1 of the display panel 10.

The slip auxiliary layer SSL may have a low modulus. That is, the slip auxiliary layer SSL may have a lower modulus than the bending protection layer BPL. For example, the slip auxiliary layer SSL may have a modulus of 0.09 MPa at −20° C. and may have a modulus of 0.03 MPa at 25° C. To this end, the slip auxiliary layer SSL may include a material that is different from a material included in the bending protection layer BPL. In an embodiment, the slip auxiliary layer SSL may include a silicon-based compound. The silicon-based compound may be an organosilicon compound containing silicon. Specifically, the silicon-based compound may include a siloxane-based polymer material. For example, the silicon-based compound may include polydimethylsiloxane.

In general, layers including an organic material such as a bending protection layer or a slip auxiliary layer may be formed by applying a material for forming the layers onto a display panel and then curing the material by using heat or light. The angle between inclined surfaces of the layers and one surface of the display panel may vary depending on the viscosity of the material for forming the layers. Specifically, a material for forming a layer including an organic material may include a monomer having fluidity and may have viscosity. When the material for forming a layer including an organic material has a high viscosity, the angle between an inclined surface of the layer and one surface of the display panel may be relatively large. In contrast, when the material for forming a layer including an organic material has a low viscosity, the angle between an inclined surface of the layer and one surface of the display panel may be relatively small.

When the modulus is high like that of the bending protection layer BPL, the viscosity of a material for forming the bending protection layer BPL may be relatively high. For example, the material for forming the bending protection layer BPL may have a viscosity of 950 cps. In this case, it may not be easy to lower the angle between the inclined surface of the bending protection layer BPL and one surface of the display panel 10. In contrast, when the modulus is low like that of the slip auxiliary layer SSL, the viscosity of a material for forming the slip auxiliary layer SSL may be relatively low. For example, the viscosity of the material for forming the slip auxiliary layer SSL may be about 39 cps to about 98 cps. Accordingly, it may be easy to lower the angle between the inclined surface of the slip auxiliary layer SSL and one surface of the display panel 10. Accordingly, the inclined surface of a layer placed between the display panel 10 and the first adhesive layer AL1 may more easily have an appropriate angle with one surface of the display panel 10. That is, the third angle θ3 formed between the third inclined surface SL3 of the slip auxiliary layer SSL and the first panel surface 10S1 of the display panel 10 may be less than the second angle θ2 formed between the second inclined surface SL2 of the bending protection layer BPL and the first panel surface 10S1 of the display panel 10.

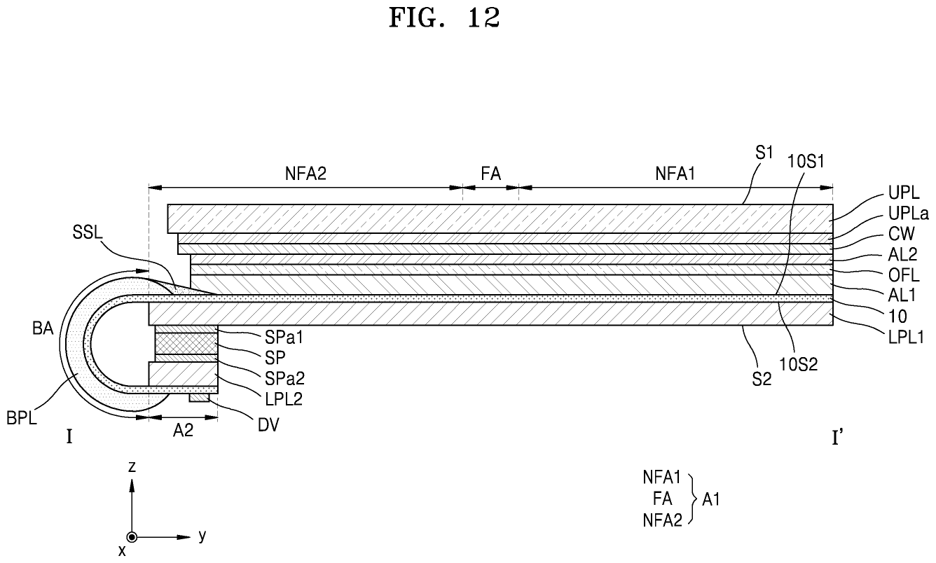

Although FIGS. 10 and 11 show that the first adhesive layer AL1 and the cover window CW are in direct contact with each other, the disclosure is not limited thereto. As shown in FIG. 12, which is a schematic cross-sectional view of the display apparatus 2 according to another embodiment, a functional layer OFL and a second adhesive layer AL2 may be disposed between the first adhesive layer AL1 and the cover window CW. In FIG. 12, the same reference numerals as those in FIGS. 9 to 11 denote the same members, and thus, duplicate descriptions are omitted.

Specifically, the functional layer OFL may be disposed between the first adhesive layer AL1 and the cover window CW. In this case, the first adhesive layer AL1 may be disposed between the functional layer OFL and the display panel 10. The first adhesive layer AL1 may attach the functional layer OFL to the display panel 10. The second adhesive layer AL2 may be disposed between the functional layer OFL and the cover window CW. Specifically, the second adhesive layer AL2 may be disposed on the functional layer OFL. The cover window CW may be attached on the functional layer OFL by the second adhesive layer AL2.

According to embodiments of the disclosure as described above, it is possible to implement a display apparatus for preventing malfunction and damage of a display panel caused by electrostatic discharge and preventing cracks in the display panel when folded. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel including a first area, a second area, and a bending area disposed between the first area and the second area;
a first adhesive layer disposed on the first area;
a cover window disposed on the first adhesive layer; and
a bending protection layer disposed on the bending area and a portion of the first area disposed adjacent to the bending area,
wherein a portion of the bending protection layer is disposed between the display panel and the first adhesive layer and the portion of the bending protection layer disposed between the display panel and the first adhesive layer includes an inclined surface.

2. The display apparatus of claim 1, wherein a portion of the first adhesive layer is disposed on the inclined surface of the bending protection layer.

3. The display apparatus of claim 1, wherein a thickness of the portion of the bending protection layer disposed between the display panel and the first adhesive layer increases toward the bending area.

4. The display apparatus of claim 1, wherein the display panel includes a first panel surface and a second panel surface opposite to the first panel surface, the bending protection layer is disposed on the first panel surface, and a first angle between the inclined surface of the bending protection layer and the first panel surface is from about 2° to about 14°.

5. The display apparatus of claim 1, wherein the cover window protrudes more than the first adhesive layer toward the bending area.

6. The display apparatus of claim 5, wherein, one side of the cover window disposed adjacent to the bending area is disposed closer to the bending area than one side of the first adhesive layer disposed adjacent to the bending area in a plan view.

7. The display apparatus of claim 1, further comprising:
a functional layer disposed between the first adhesive layer and the cover window; and
a second adhesive layer disposed between the functional layer and the cover window.

8. The display apparatus of claim 7, wherein the functional layer includes a polarizing film.

9. The display apparatus of claim 1, wherein the first area includes a first non-folding area, a second non-folding area, and a foldable area disposed between the first non-folding area and the second non-folding area, and
wherein the first non-folding area is disposed spaced apart from the bending area, the second non-folding area is disposed adjacent to the bending area, and the display panel is foldable in the foldable area.

10. The display apparatus of claim 1, further comprising:
an upper protective layer disposed on the cover window; and
an upper protective layer adhesive layer disposed between the cover window and the upper protective layer.

11. A display apparatus comprising:
a display panel including a first area, a second area, and a bending area disposed between the first area and the second area;
a first adhesive layer disposed on the first area;
a cover window disposed on the first adhesive layer;
a bending protection layer disposed on the bending area and a portion of the first area disposed adjacent to the bending area; and
a slip auxiliary layer disposed between the bending protection layer and the first adhesive layer and including a material that is different from a material included in the bending protection layer,
wherein a portion of the slip auxiliary layer is disposed between the display panel and the first adhesive layer, and the portion of the slip auxiliary layer disposed between the display panel and the first adhesive layer includes an inclined surface.

12. The display apparatus of claim 11, wherein a portion of the first adhesive layer is disposed on the inclined surface of the slip auxiliary layer.

13. The display apparatus of claim 11, wherein a thickness of the portion of the slip auxiliary layer disposed between the display panel and the first adhesive layer increases toward the bending area.

14. The display apparatus of claim 11, wherein the display panel includes a first panel surface and a second panel surface opposite to the first panel surface, the slip auxiliary layer is disposed on the first panel surface, and a first angle between the inclined surface of the slip auxiliary layer and the first panel surface is from about 2° to about 14°.

15. The display apparatus of claim 11, wherein the cover window protrudes more than the first adhesive layer toward the bending area.

16. The display apparatus of claim 15, wherein, one side of the cover window disposed adjacent to the bending area is disposed closer to the bending area than one side of the first adhesive layer disposed adjacent to the bending area in a plan view.

17. The display apparatus of claim 11, further comprising:
a functional layer disposed between the first adhesive layer and the cover window; and
a second adhesive layer disposed between the functional layer and the cover window.

18. The display apparatus of claim 17, wherein the functional layer includes a polarizing film.

19. The display apparatus of claim 11, wherein the first area includes a first non-folding area, a second non-folding area, and a foldable area disposed between the first non-folding area and the second non-folding area, and
wherein the first non-folding area is disposed spaced apart from the bending area, the second non-folding area is disposed adjacent to the bending area, and the display panel is foldable in the foldable area.

20. The display apparatus of claim 11, further comprising:
an upper protective layer disposed on the cover window; and
an upper protective layer adhesive layer disposed between the cover window and the upper protective layer.
